(19) United States
(12) Patent Application Publication
(10) Pub. No.: US 2008/0150026 A1
(43) Pub. Date: Jun. 26, 2008

(54) METAL-OXIDE-SEMICONDUCTOR FIELD EFFECT TRANSISTOR WITH AN ASYMMETRIC SILICIDE

(75) Inventors: Oh-Jung Kwon, Hopewell Junction, NY (US); Hoki Kim, Hopewell Junction, NY (US); Jack A. Mandelman, Flat Rock, NC (US); Tak H. Ning, Yorktown Heights, NY (US)

Correspondence Address: SCULLY, SCOTT, MURPHY & PRESSER, P.C., 400 GARDEN CITY PLAZA, Suite 300, GARDEN CITY, NY, 11530, US

(73) Assignee: INTERNATIONAL BUSINESS MACHINES CORPORATION, Armonk, NY (US)

(21) Appl. No.: 11/616,183

(22) Filed: Dec. 26, 2006

(51) Int. Cl. H01L 29/786

(52) U.S. Cl. 257/347; 257/E29.273

(57) ABSTRACT

A MOSFET formed using asymmetric silicidation between source and drain induces higher leakage between the body and the source than between the body and the drain. Implementation of such a MOSFET on an SOI substrate reduces or eliminates floating body effect for consistent on-current and turn-on time. The asymmetry between the source and the drain is introduced by forming different silicides between the source and the drains with a thicker silicide on the source, or by recessing the source material so that the source silicide is formed closer to the buried oxide layer than the drain silicide.

### FIELD OF THE INVENTION

The present invention relates to semiconductor devices, and particularly, to metal oxide semiconductor filed effect transistors (MOSFETs) with an asymmetric silicide between source and drain, or “asymmetric silicide MOSFETs”.

### BACKGROUND OF THE INVENTION

On one hand, a metal oxide semiconductor field effect transistors (MOSFET) built on a silicon-on-insulator (SOI) substrate in general offer advantages over a MOSFET with comparable dimensions that is built on a bulk substrate by providing a higher on-current and lower parasitic capacitance between the body and other MOSFET components. On the other hand, a MOSFET built on an SOI substrate tends to have less consistency in the FET operation due to history effect, or floating body effect, in which the potential of the body, and subsequently, the timing of the turn-on and the on-current of the SOL MOSFET are dependent on the past history of the SOI MOSFET. Furthermore, the level of leakage current also depends on the voltage of the floating body, which poses a challenge in the design of a low power SOI MOSFET.

Therefore, there exists a need for a structure that provides the advantages of SOI MOSFET devices while minimizing or eliminating the history effect of the SOI MOSFET devices.

Furthermore, there exists a need for a structure that provides the advantages of SOI MOSFET devices while minimizing the variations in the leakage current to enable a low power SOI MOSFET design.

### SUMMARY OF THE INVENTION

The present invention addresses the needs described above by providing SOI MOSFET structures with an asymmetric silicide between the source and the drain and methods of fabricating the same.

Specifically, the present invention provides an SOI MOSFET with a thicker silicide in the source than in the drain according to a first embodiment.

The present invention provides an SOI MOSFET with a recessed silicide in the source and a non-recessed silicide in the drain according to a second embodiment.

According to the first embodiment of the present invention, a metal-oxide-semiconductor field effect transistor (MOSFET) structure is disclosed, which comprises:

a body located within a semiconductor substrate;

a source metal silicide located in a source and in a portion of the body; and

a drain metal silicide located in a drain and not contacting the body.

Preferably, the MOSFET structure further contains a portion of the source that is not silicided and directly contacts a spacer. Also, preferably, the source metal silicide is thicker than the drain metal silicide.

The MOSFET structure may comprise a bulk substrate, a silicon-on-insulator (SOI) substrate, or a hybrid substrate which comprise a bulk substrate portion and an SOI substrate portion. Preferably, the MOSFET structure comprises a silicon-on-insulator substrate.

Optionally, the source metal silicide and the drain metal silicide may be two different materials. In one version of the present invention, the source metal silicide is a cobalt silicide and the drain silicide is a nickel metal alloy silicide, for example, a nickel platinum silicide (Ni₁₋ₓPtₓSi) with an atomic ratio between nickel and platinum of about 19:1 (x˜0.05).

According to the second embodiment of the present invention, a metal-oxide-semiconductor field effect transistor (MOSFET) structure is disclosed, which comprises a source metal silicide having a first portion located at a level lower than an extension implant region.

Preferably, the source metal silicide has a second portion, wherein the second portion contacts a spacer and is contiguous with the first portion.

More preferably, the source metal silicide has a third portion having a vertical sidewall, wherein the second portion contacts the first portion and the third portion.

The MOSFET structure may comprise a bulk substrate, a silicon-on-insulator (SOI) substrate, or a hybrid substrate which comprise a bulk substrate portion and an SOI substrate portion. Preferably, the MOSFET structure comprises a silicon-on-insulator substrate. If an SOI substrate is utilized, the first portion may or may not contact a buried oxide layer.

The MOSFET structure preferably comprises a source metal contact that directly contacts the first portion. The MOSFET structure preferably further comprises a drain metal contact that directly contacts a drain, wherein a bottom of the source metal contact is located at a lower level than a bottom of the drain metal contact.

While the invention has been described in terms of specific embodiments, it is evident in view of the foregoing description that numerous alternatives, modifications and variations will be apparent to those skilled in the art. Accordingly, the invention is intended to encompass all such alternatives, modifications and variations which fall within the scope and spirit of the invention and the following claims.

### BRIEF DESCRIPTION OF THE DRAWINGS

FIG. 1A is a top-down view of an SOI MOSFET structure according to the first and the second embodiments of the present invention.

FIG. 1B is a cross-sectional view of an SOI MOSFET structure taken in the plane of A-A′ in FIGS. 1A-8A according to the first and the second embodiments of the present invention.

FIGS. 2A-8A are sequential top-down views of an SOI MOSFET structure according to the first embodiment of the present invention.

FIGS. 2B-8 are sequential cross-sectional views of an SOI MOSFET structure taken in the plane of A-A′ in FIGS. 2A-8A according to the first embodiment of the present invention.

FIGS. 9A-13A are sequential top-down views of an SOI MOSFET structure according to the second embodiment of the present invention.

FIGS. 9B-13B are sequential cross-sectional views of an SOI MOSFET structure taken in the plane of A-A′ in FIGS. 9A-13A according to the second embodiment of the present invention.

FIG. 14A is a top-down view of an alternative SOI MOSFET structure in a case in which the thickness of the source metal silicide is increased compared to the structure in FIGS. 13A-13B.

FIG. 14B is a cross-sectional view of the alternative SOI MOSFET structure taken in the plane of A-A′ in FIG. 13A in a case wherein the thickness of the source metal silicide is increased compared to the structure in FIGS. 13A-13B.

FIG. 15 is a magnified view of the structures around the source in FIG. 13B.

### DETAILED DESCRIPTION OF THE INVENTION

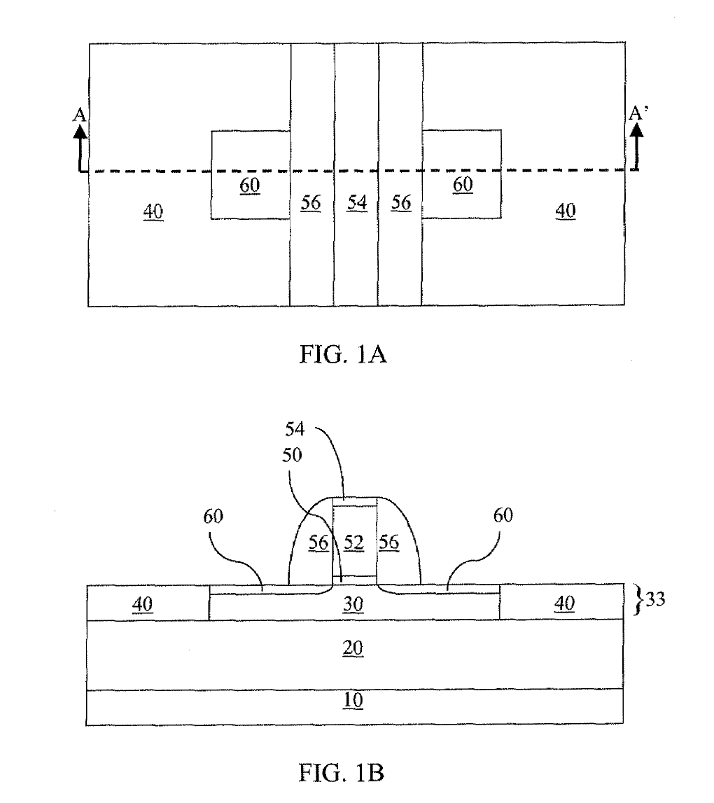

Referring to FIGS. 1A and 1B, a MOSFET structure at an initial stage of manufacturing according to the first and the second embodiments of the present invention is shown. FIG. 1A is a top-down view and FIG. 1B is a cross-sectional view along the plane A-A′ in FIG. 1A. Throughout the accompanying figures, the relationship between each pair of figures with the same figure number is the same as the relationship between FIG. 1A and FIG. 1B. While the present invention is described using an SOI substrate, implementation of the present invention on other substrates are straightforward.

As shown in FIGS. 1A and 1B, an SOI substrate with a handler wafer 10, a buried oxide layer 20, and a top semiconductor layer 33 contacting the buried oxide layer 20 is provided. Shallow trench isolation (STI) 40 is formed in the top semiconductor layer 33 to define an active area of an SOI MOSFET. A gate dielectric 50, a gate conductor 52, and an optional gate cap 54 are deposited and patterned to form a gate stack. Extension implant regions 60 are formed under the surface of the top semiconductor layer 33 to define the extensions for the source and for the drain. The body 30 at this point is the volume of the active area excluding the volume of the extension implant regions 60. Spacers 56 are formed around the gate stack. The spacers 56 contact the extension implant regions 60. The top semiconductor layer 33 at this point comprises the body 30, the STI 40, and the extension implant region 60.

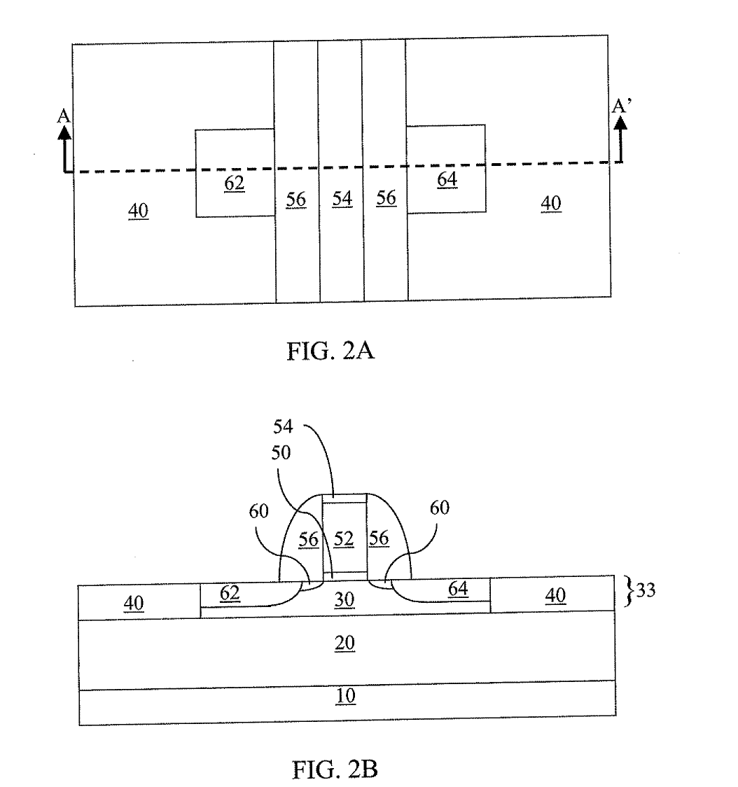

Referring to FIGS. 2A and 2B, a subsequent structure according to the first embodiment of the present invention is shown. A source and drain implantation is performed at this point preferably with amorphization implants. Halo implant or other extension implants may be used to tailor device performance. Optionally, embedded silicon alloy materials may be introduced to the source and drain regions at this point. In a PMOSFET, p-type dopants are introduced into the source 62 and into the drain 64. In an NMOSFET, n-type dopants are introduced into the source 62 and into the drain 64. Preferably, a single implant is used to deliver the dopants to both the source 62 and the drain 64. The source and drain implants deliver a substantially higher doping, preferably by more than one order of magnitude, into the source 62 and into the drain 64. After the source and drain implantation, the extension implant regions 60 are reduced in size to form actual source and drain extensions in an operational MOSFET as shown in FIGS. 2A and 2B.

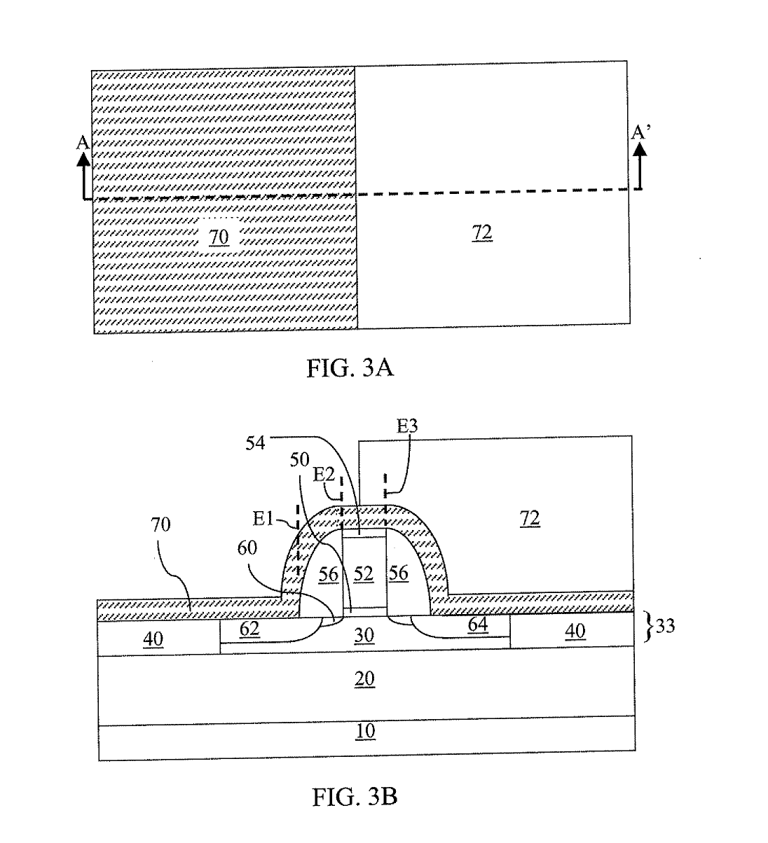

Referring to FIGS. 3A and 3B, a dielectric layer 70 is deposited over the entire top surface of the semiconductor structure above. The dielectric layer 70 is preferably conformal. The dielectric layer 70 may comprise a silicon nitride, a silicon oxide, a silicon oxynitride, or a stack thereof. The dielectric layer 70 is preferably a silicon nitride. The thickness of the dielectric layer 70 is in the range from about 10 nm to about 100 nm, and preferably in the range from about 20 nm to about 60 nm. Various methods of deposition including chemical vapor deposition (CVD) may be utilized to form the dielectric layer 70.

Subsequently, a photoresist 72 is applied over the top surface of the semiconductor structure and patterned as shown in FIGS. 3A-3B to expose a portion of the dielectric layer 70 on the side of the source 62. If a gate cap 54 is employed and is present in the structure, the edge of the photoresist 72 may be placed between the first edge E1, which is defined by the outer edge of the bottom of the spacer 56 on the side of the source 62, and the third edge E3, which is defined by the boundary of the gate conductor 52 with the adjoining spacer 56 on the side of the drain 64. Subsequent etching of the dielectric layer 70 exposes semiconductor material only from the source 62, but does not expose the gate conductor 52, e.g., gate polysilicon from underneath the gate cap 54. If a gate cap 54 is not employed and therefore not present in the structure at this point, the edge of the photoresist 72 may be placed between the first edge E1 and the second edge E2, which is defined by the boundary of the gate conductor 52 with the adjoining spacer 56 on the side of the source 62.

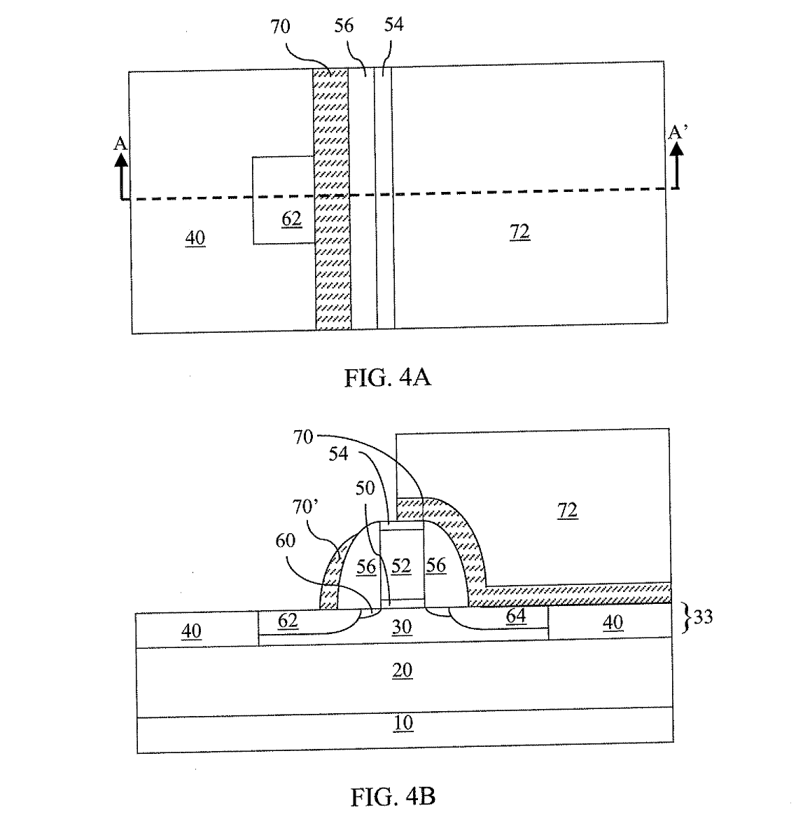

Referring to FIGS. 4A and 4B, the pattern formed on the photoresist 72 is transferred into the dielectric layer 70 by a reactive ion etching (RIE). The RIE forms a temporary spacer 70′ out of the dielectric layer 70 on the side of the source 62. The RIE may expose a portion of the spacer 56 on the side of the source 62 depending on the overlay of the edge of the photoresist 72 over the gate structure. The RIB may also expose a portion of the gate cap 54 depending on the overlay of the edge of the photoresist 72 over the gate structure. The RIE is preferably selective to the underlying layers, that is, selective to the semiconductor material in the source 62, to the dielectric in the shallow trench isolation 40, to the spacer 56, and to the optional gate cap 54.

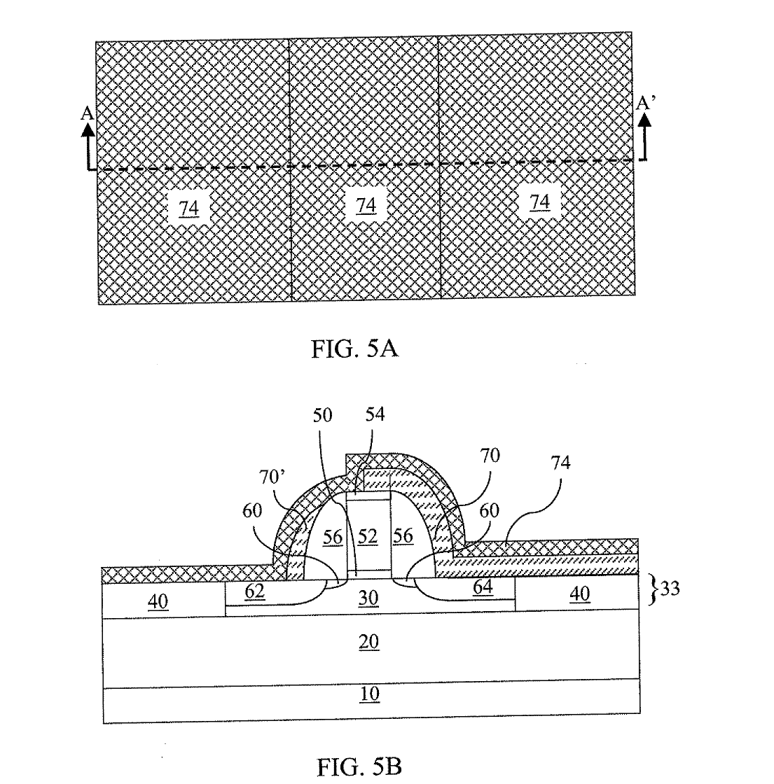

Referring to FIGS. 5A and 5B, the photoresist 72 is removed and a first metal 74 is deposited over the top surface of the semiconductor structure above. The first metal 74 may be nickel, nickel platinum alloy, cobalt, tantalum, tungsten, molybdenum, titanium, another refractory metal, or an alloy thereof. The thickness of the first metal 74 is selected to provide enough material to form a thick silicide in subsequent processing steps. The first metal 74 is reacted with the exposed semiconductor material in the source 62 in FIG. 5B.

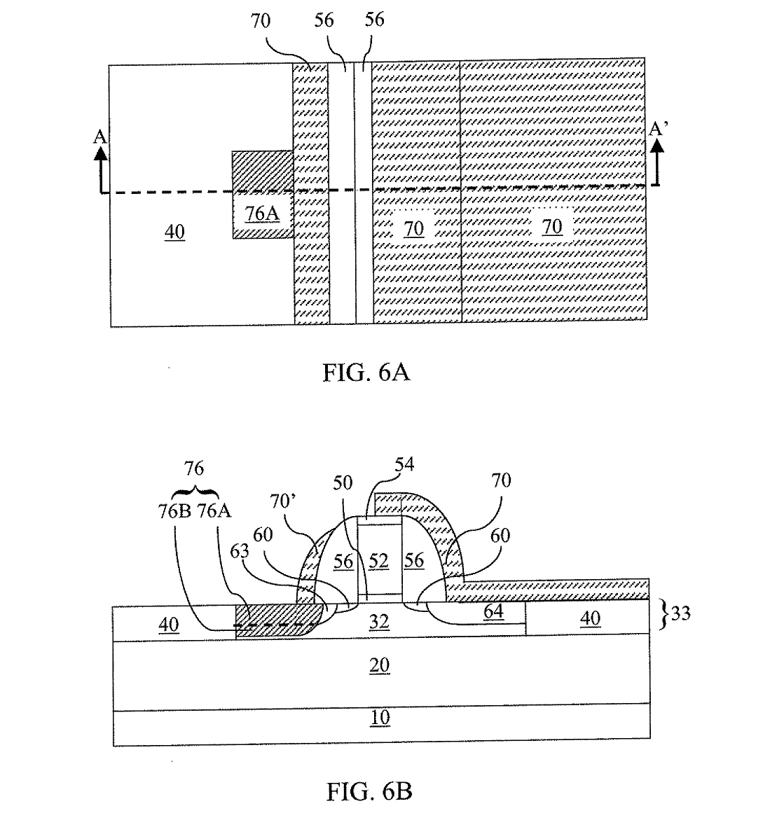

Referring to FIGS. 6A and 6B, the first metal 74 during a silicidation process consumes all of the doped semiconductor material directly underneath the exposed surface of the source 62 and to form a first portion 76A of the source. The first portion 76A of the source is silicided at this point. Furthermore, a portion 76B of the body 30 in FIG. 5B is also silicided by the reaction of the first metal 74 with the semiconductor material in the body 30 to form a silicided portion 76B of the body 30. The unreacted first metal 74 is removed to form a structure shown in FIGS. 6A and 6B.

Preferably, a portion of the source 62 does not subsequently react with the first metal 74 to form a silicide. The unsilicided portion 63 of the source contacts a lower surface of spacer 56 as shown in FIGS. 6A and 6B. At this point, the source (63, 76A) comprises an unsilicided portion 63 and a silicided portion 76A, which is “the first portion” 76A of the source.

According to the first embodiment of the present invention, the body 30 at this point comprises an unsilicided portion 32 of the body 30 and a silicided portion 76B of the body 30. The silicided portion 76B of the body 30 may or may not touch the underlying buried oxide layer 20.

The two silicides (76A, 76B) are formed by the reaction of the first metal 74 with the semiconductor material only on the side of the source (63, 76A) and are therefore, designated as “source metal silicide” 76. In other words, the source metal silicide 76 comprises the first portion 76A of the source (63, 76A) and the silicided portion 76B of the body (32, 76B).

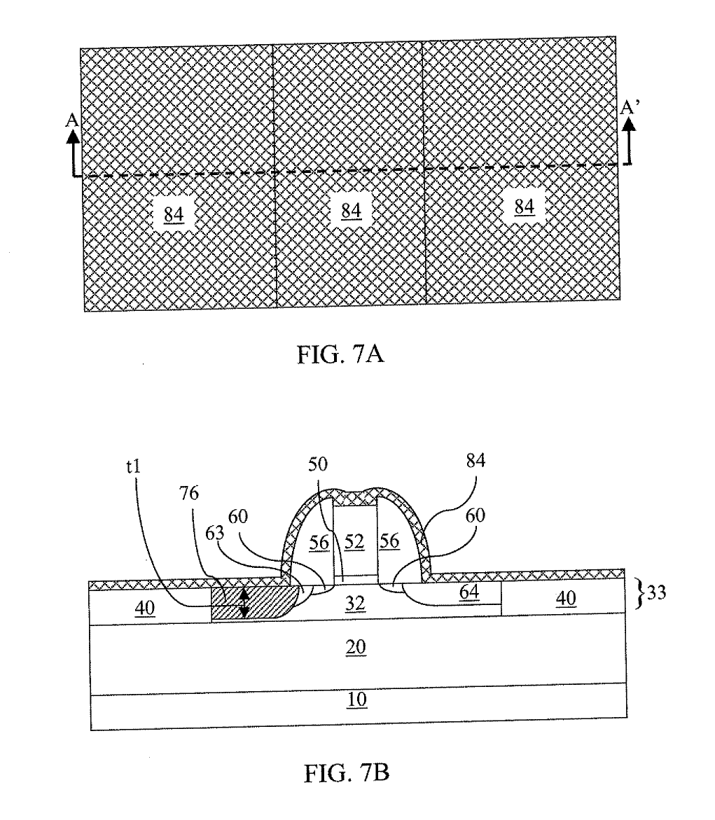

Thereafter, the patterned insulator layer 70 and the temporary spacer 70′ are removed either by a RIE or by a wet etch, If an optional gate cap 54 is present in the structure, the gate cap 54 is also removed by a RIE or by a wet etch. After a suitable preclean of semiconductor surfaces, particularly, the surfaces of the gate conductor 52 and of the drain 64, a second metal 84 is deposited as shown in FIGS. 7A and 7B. The second metal 84 may be nickel, nickel platinum alloy, cobalt, tantalum, tungsten, molybdenum, titanium, other refractory metal or an alloy thereof. Preferably, the second metal 84 is a different material from the first metal 74. The thickness of the first metal 84 is selected to form a thin silicide, that is, to form a silicide with less thickness (t2 in FIG. 5B) in subsequent processing steps than the thickness t1 of the source metal silicide 76 as shown in FIG. 7B.

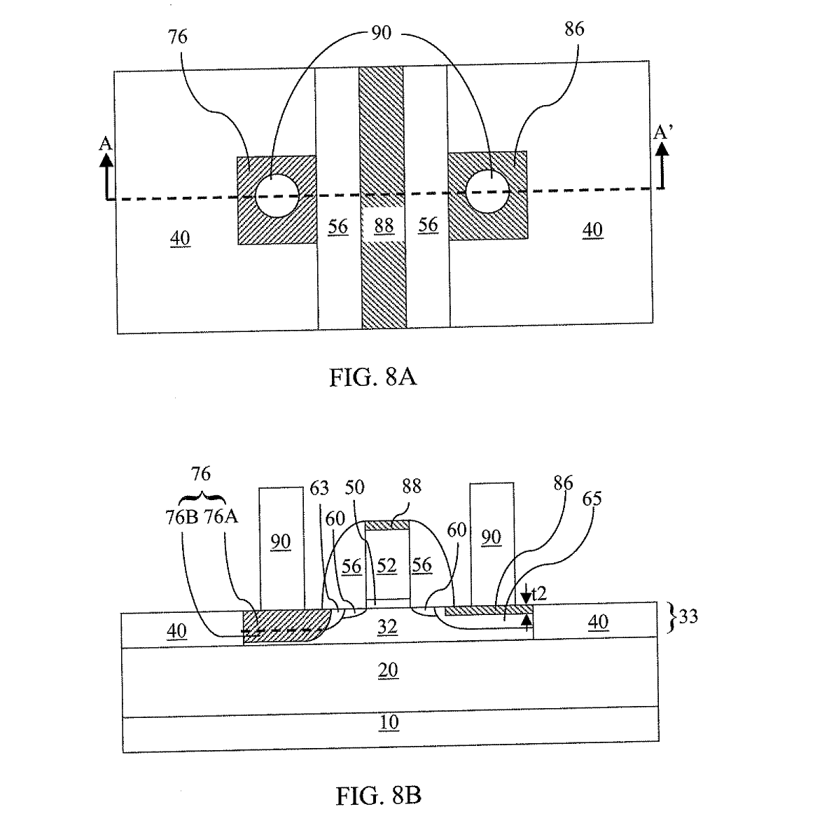

The second metal 84 is reacted by a silicidation process with the underlying semiconductor material in the drain 64 and in the gate conductor 54 in FIGS. 7A and 7B to from a drain metal silicide 86 and a gate metal silicide 88 as shown in FIGS. 8A and 8B. The reaction of the second metal on the source side is minimal due to the presence of the silicided portion 63, i.e., due to a lack of unsilicided semiconductor material on the source side. The unreacted second metal 84 is thereafter removed The drain (86,65) at this point comprises a drain metal silicide 86 and an unsilicided drain 65. Thereafter, a middle-of-the-line (MOL) dielectric (not shown) is deposited and source and drain metal contacts 90 are formed as shown in FIGS. 8A and 8B.

The structure according to the first embodiment of the present invention at this point comprises:

the body (32, 76B) located within the semiconductor substrate;

the source metal silicide (76A, 76B) located in the first portion 76A of the source (63, 76A) and in the silicided portion 76B of the body (32, 76B); and

the drain metal silicide 86 located in the drain (86, 65) and not contacting the body (32, 76B).

Furthermore, the structure according to the first embodiment of the present invention further comprises the second portion 63 of the source (63, 76A), wherein the second portion 63 is not silicided and directly contacts a spacer 56.

According to the second embodiment of the present invention, a semiconductor structure as shown in FIGS. 1A and 1B are provided first.

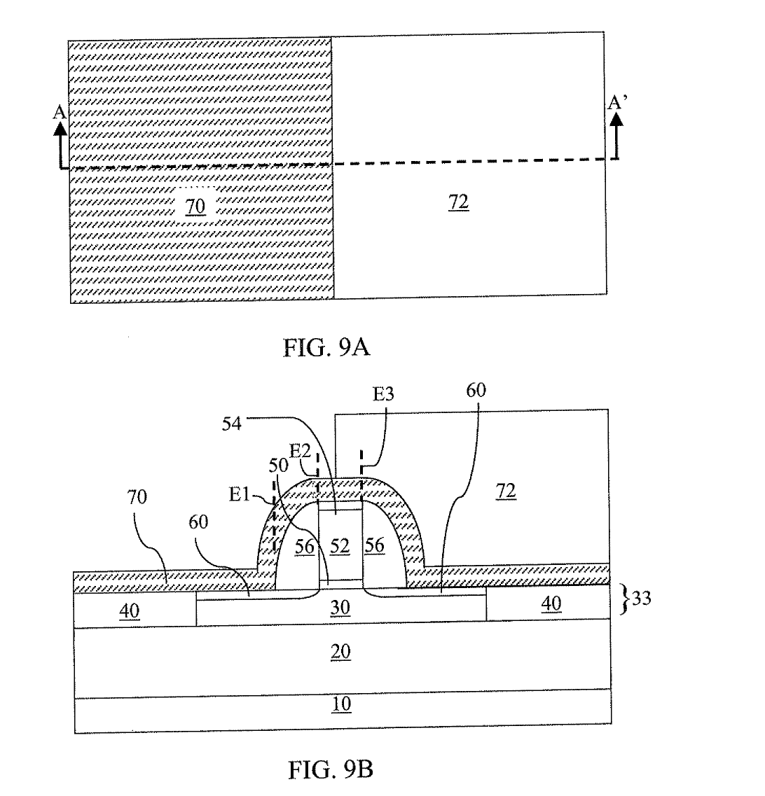

Referring to FIGS. 9A and 9B, a dielectric layer 70 is deposited over the entire top surface of the semiconductor structure above. A photoresist 72 is applied over the top surface of the semiconductor structure and patterned as shown in FIGS. 9A-9B to expose a portion of the dielectric layer 70 on the side of the source to be formed. In FIGS. 9A and 9B, the side of the source is to the left of the gate structure and does not have an overlying photoresist 72. A gate cap 54 may optionally be present. The structural and methodical aspects of the dielectric layer 70, of the photoresist 72, of the optional gate cap 54, and the three edges E1, E2, and E3 according to the second embodiment of the present invention are identical to those according to the first embodiment as described in the paragraphs accompanying FIGS. 3A and 3B.

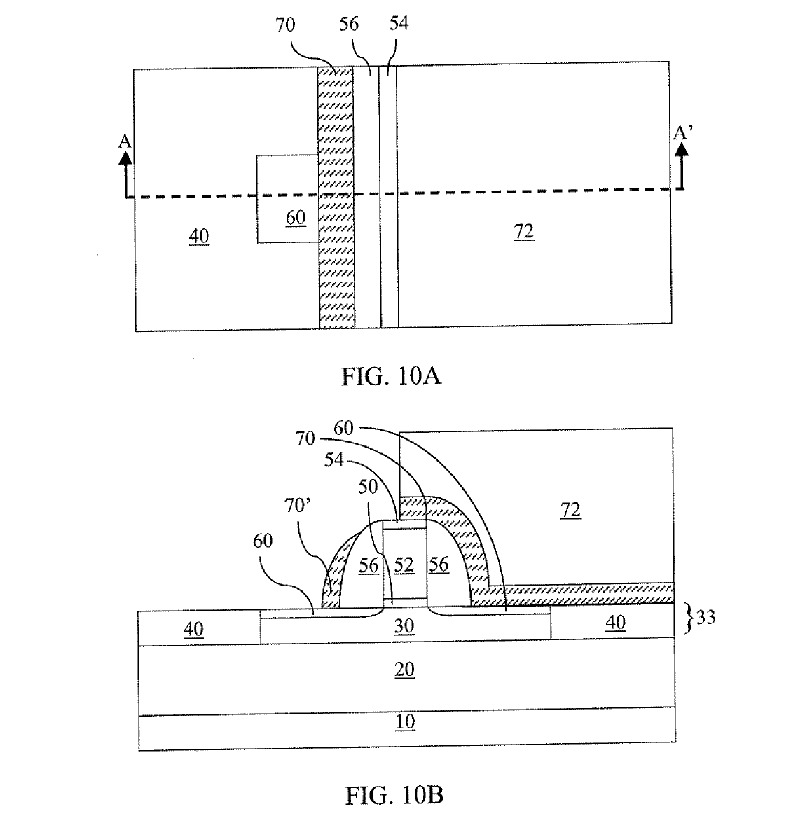

Referring to FIGS. 10A and 10B, the pattern formed on the photoresist 72 is transferred into the dielectric layer 70 by a first reactive ion etching (RIE). The first RIE forms a temporary spacer 70′ out of the dielectric layer 70 on the side of the source 62. The first RIE may expose a portion of the spacer 56 on the exposed side depending on the overlay of the edge of the photoresist 72 over the gate structure. The first RIE may also expose a portion of the gate cap 54 depending on the overlay of the edge of the photoresist 72 over the gate structure. The first RIE is preferably selective to the underlying dielectric layers, that is, to the dielectric in the shallow trench isolation 40, to the spacer 56, and to the optional gate cap 54. Preferably, however, the first RIE is not selective to the semiconductor material in the extension implant regions 60 or to the semiconductor material in the body 30.

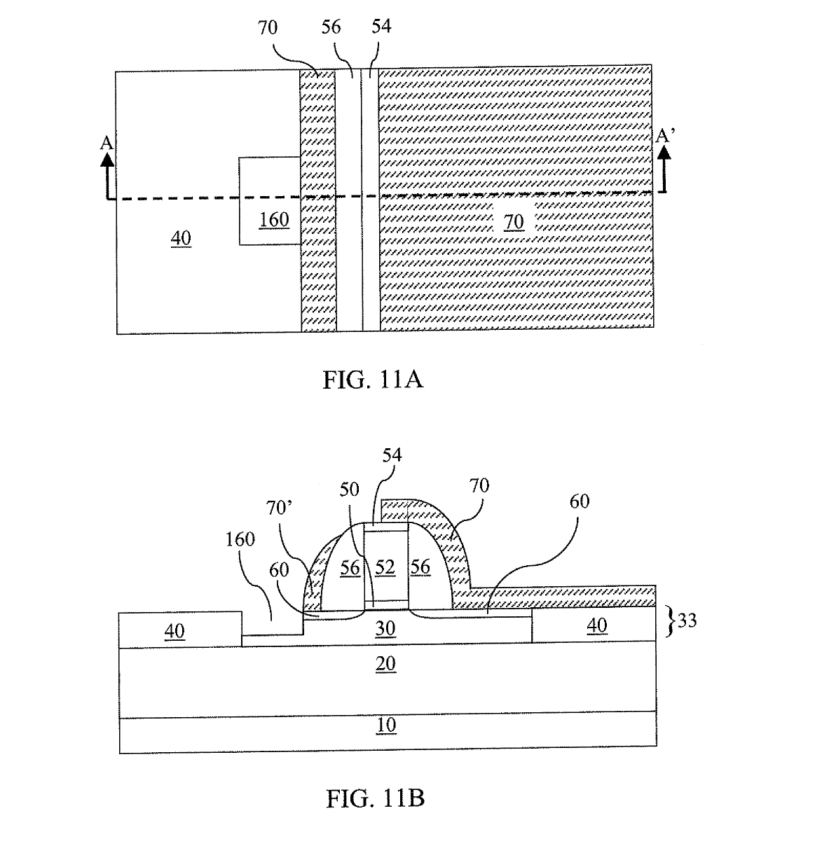

Referring to FIGS. 11A and 11B, a second RIE is employed after the first RIE described above to etch a source recess region 160. Preferably, the second RIB etches the semiconductor material in the extension implant regions 60 and some of the semiconductor material in the body 30 selective to the dielectric in the shallow trench isolation 40, to the spacer 56, and to the optional gate cap 54. Preferably, the depth of the source recess region is deeper than the thickness of the extension implant region 60.

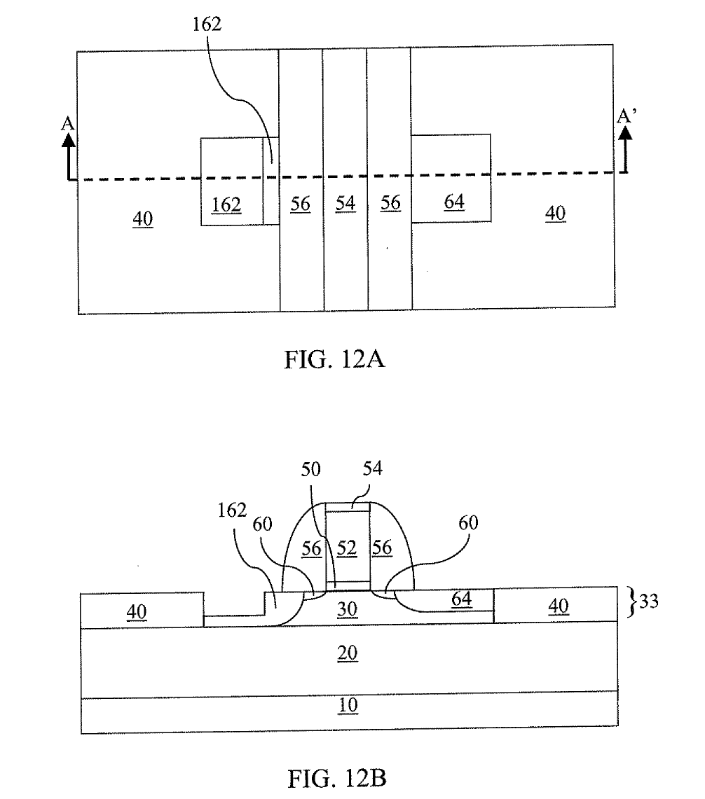

Referring to FIGS. 12A and 12B, the dielectric layer 70 is thereafter removed either by a wet etch or a third RIE, preferably by a wet etch. A source and drain implantation is performed at this point preferably with amorphization implants. Halo implant or other extension implants may be used to tailor device performance at this point. Optionally, embedded silicon alloy materials may be introduced to the source and drain regions at this point. Preferably, a single implant is used to deliver the dopants to both the source 162 and the drain 64. The source and drain implantation deliver a substantially higher doping than the doping in the extension implant region, preferably by more than one order of magnitude, into the source 162 and into the drain 64. After the source and drain implantation, the extension implant regions 60 are reduced in size to define actual source and drain extensions in an operational MOSFET as shown in FIGS. 12A and 12B. Due to the recess present in the source recess region 160, the source 162 is formed deeper, that is, closer to the buried oxide layer 20 and vertically farther away from the gate dielectric 50, than the drain 60. The source 162 has at this point two levels of top surfaces, a first top surface that is recessed substantially below the bottom surface of the gate dielectric 52 and a second top surface that is substantially at the same level as the bottom surface of the gate dielectric 52.

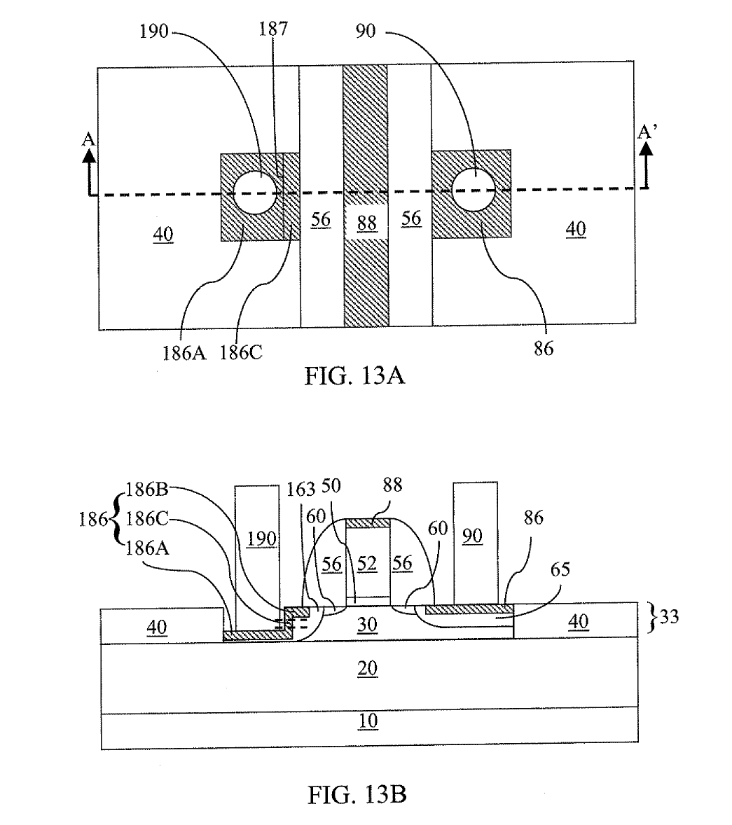

Referring to FIGS. 13A and 13B, the optional gate cap 54 is removed either by a wet etch or by a RIE. A metal is deposited on the top surface of the semiconductor structure and reacted with the exposed semiconductor surfaces, i.e., the semiconductor surfaces of the source 162, of the gate conductor 52, and of the drain 64 in FIGS. 12A and 12B. The unreacted metal is removed from the semiconductor structure. Thereafter, a middle-of-the-line (MOL) dielectric (not shown) is deposited and a source metal contact 190 and a drain metal contact 90 are formed.

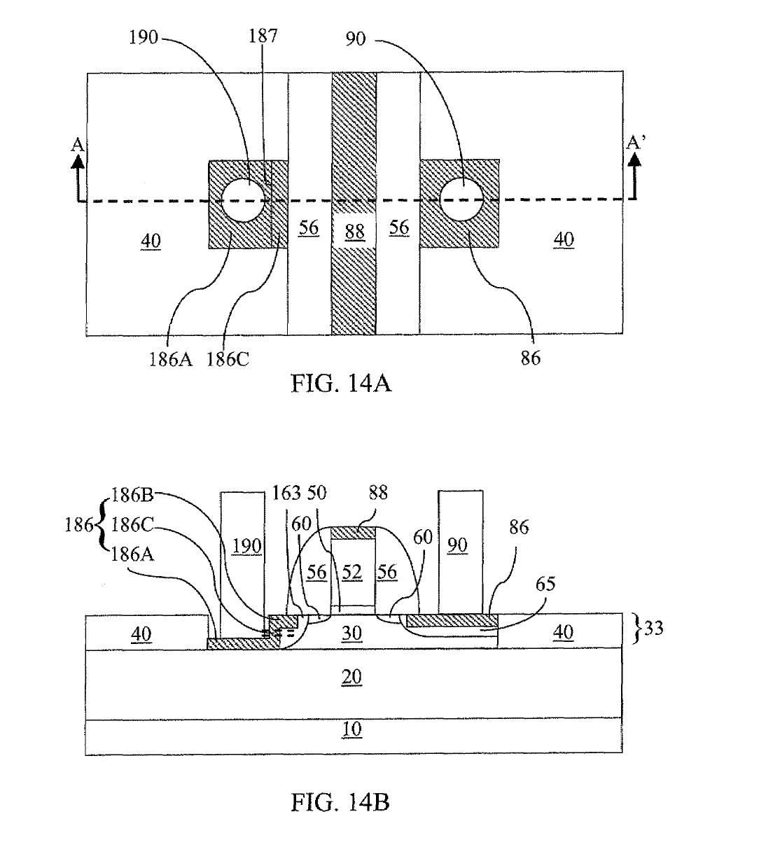

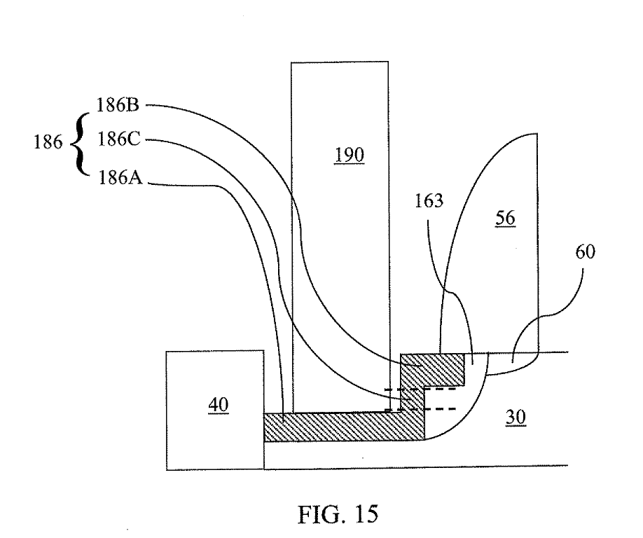

FIGS. 13A and 13B are resulting structures if the silicidation of the first portion 186A of the source (186, 163) does not contact the buried oxide layer 20. FIGS. 14A and 14B are resulting structures if the silicidation of the first portion 186A of the source (186, 163) proceeds to and contacts the top of the buried oxide layer 20. FIG. 15 is a magnified view of the structure in FIG. 13B around the source showing the details of the structure according to the second embodiment of the present invention.

The source (186, 163) at this point comprises:

a first portion 186A of source metal silicide 186 that is located at a level lower than an extension implant region 60;

a second portion 186B of the source metal silicide 186, wherein the second portion contacts a spacer 56 and is contiguous with the first portion 186A;

a third portion 186C having a vertical sidewall, wherein the third portion 186C contacts the first portion 186A and the second portion 186B; and

an unsilicided portion 163 of the source that contacts a spacer 56.

The drain (86, 65) at this point comprises a drain metal silicide 86 and an unsilicided portion 65 of the drain (86, 65).

The structure according to the second embodiment of the present invention also comprises the source metal contact 190 that directly contacts the first portion 186A of the source (186A, 163) and the drain metal contact 90 that directly contacts the drain (86, 65), wherein the bottom of the source metal contact 190 is located at a lower level than the bottom of the drain metal contact 90.

The asymmetric silicide MOSFETs according to the first and the second embodiments of the present invention enable asymmetric leakage current flow between the body-source junction and the body-drain junction. Specifically, a higher leakage at the body-source junction compared to a leakage at the body-drain junction reduces or eliminates the floating body effect by making the potential of the body approach the potential at the source.

The source according to the present invention is the terminal of a MOSFET from which the carriers are supplied. In an n-type MOSFET (NMOSFET), of the two terminals that are connected to the body of the NMOSFET, the source is the terminal that is connected to a lower voltage, and therefore, supplies electrons to the channel, i.e., electrons flow out of the source. In a p-type MOSFET (PMOSFET), of the two terminals that are connected to the body of the NMOSFET, the source is the terminal that is connected to a higher voltage, and therefore, supplies holes to the channel, i.e., holes flow out of the source.

The asymmetric silicide MOSFETs may be employed in conjunction with regular SOI devices, i.e., SOI devices with substantially symmetric source and drain silicidation, in a circuit comprising SOI devices to provide MOSFETs with high immunity to floating body effects, or history effects. For example, both the source and the drain of the regular SOI devices may have the same silicidation as the drain of the MOSFETs with an asymmetric silicide. Alternatively, the MOSFETs with an asymmetric silicide maybe employed in conjunction with regular SOI devices in a circuit comprising SOI devices to provide MOSFETs with low power consumption by reducing leakage currents due to unstable body potential. In another application, the reduced floating body effect may be utilized to reduce an uncertainty window in a critical timing circuit.

What is claimed is:

1. A metal-oxide-semiconductor field effect transistor (MOSFET) structure, comprising:
a body located within a semiconductor substrate;
a source metal silicide located in a first portion of a source and in a portion of said body; and
a drain metal silicide located in a drain and not contacting said body.

2. The MOSFET structure of claim 1, further comprising a second portion of said source, wherein said second portion is not silicided and directly contacts a spacer.

3. The MOSFET structure of claim 2 wherein said source metal silicide is thicker than said drain metal silicide.

4. The MOSFET structure of claim 3 further comprising a silicon-on-insulator substrate.

5. The MOSFET structure of claim 4 wherein said source metal silicide and said drain metal silicide are two different materials.

6. The MOSFET structure of claim 5, wherein said source metal silicide is a cobalt silicide and said second metal silicide is a nickel metal alloy silicide.

7. A metal-oxide-semiconductor field effect transistor (MOSFET) structure, comprising a source metal silicide having a first portion located at a level lower than an extension implant region.

8. The MOSFET structure of claim 7, wherein said source metal silicide has a second portion, wherein said second portion contacts a spacer and is contiguous with said first portion.

9. The MOSFET structure of claim 8, wherein said source metal silicide has a third portion having a vertical sidewall, wherein said third portion contacts said first portion and said second portion.

10. The MOSFET structure of claim 9, further comprising a silicon-on-insulator (SOD substrate.

11. The MOSFET structure of claim 10, further comprising a source metal contact that directly contacts said first portion.

12. The MOSFET structure of claim 11, further comprising a drain metal contact that directly contacts a drain, wherein a bottom of said source metal contact is located at a lower level than a bottom of said drain metal contact.

13. The MOSFET structure of claim 11, wherein said first portion contacts a buried oxide layer.
